(19) United States
(12) Patent Application Publication
(10) Pub. No.: US 2014/0145745 A1
(43) Pub. Date: May 29, 2014

(54) TEST SYSTEM FOR TESTING A CMOS IMAGE SENSOR AND A DRIVING METHOD THEREOF

(71) Applicant: SAMSUNG ELECTRONICS CO., LTD., Gyeonggi-do (KR)

(72) Inventors: Hyung-Sun Ryu, Gyeonggi-do (KR); Jang-Hwan Kim, Gyeonggi-do (KR); Hyung-Jung Yong, Gyeonggi-do (KR); Ji-Nyeong Yun, Gyeonggi-do (KR); Dae-Hee Lee, Seoul (KR); Seong-Kwan Lee, Gyeonggi-do (KR); Yun-Bong Jang, Gyeonggi-do (KR); Shin-Ki Jeong, Seoul (KR)

(73) Assignee: SAMSUNG ELECTRONICS CO., LTD., Gyeonggi-do (KR)

(21) Appl. No.: 14/011,863

(22) Filed: Aug. 28, 2013

(30) Foreign Application Priority Data
Nov. 26, 2012 (KR) 10-2012-0134684

(51) Int. Cl. G01R 31/319

(52) U.S. Cl. CPC G01R 31/31917
USPC 324/762.01

(57) ABSTRACT

A test system including a test device configured to transmit an input signal and a control signal to at least one complementary metal-oxide semiconductor (CMOS) image sensor via a probe card, and an interface board configured to map the probe card and the test device. The interface board includes an output receiver configured to receive an image signal from the at least one CMOS image sensor and transform the image signal into image data.

### CROSS-REFERENCE TO RELATED APPLICATION

This application claims priority under 35 U.S.C. §119 to Korean Patent Application No. 10-2012-0134684 filed on Nov. 26, 2012 in the Korean Intellectual Property Office, the disclosure of which is incorporated by reference herein in its entirety.

### BACKGROUND

1. Technical Field

The inventive concept relates to test systems, and more particularly, to a test system for testing a complementary metal-oxide semiconductor (CMOS) image sensor.

2. Discussion of the Related Art

In general, image sensors are semiconductor devices that transform an optical image into an electrical signal. Image sensors are used in digital cameras, camera modules and other imaging devices, for example. A complementary metal-oxide semiconductor (CMOS) image sensor can potentially be implemented with fewer components, use less power, and/or provide faster readout than a charge-coupled device (CCD) image sensor.

A final output signal of the CMOS image sensor is generated by an image processor. Thus, an output of the image processor can be used to test operating characteristics of the CMOS image sensor. However, since hundreds of thousands to millions of unit pixels may be included in the CMOS image sensor, it takes a lot of time to test all of the pixels. Further, if a data transmission method employed by the CMOS image sensor is changed, the test system may not work with the new data transmission method.

### SUMMARY

Exemplary embodiments of the inventive concept provide a test system capable of reducing a time for testing a complementary metal-oxide semiconductor (CMOS) image sensor.

Exemplary embodiments of the inventive concept provide a test system capable of receiving high-speed serial data from a CMOS image sensor.

Exemplary embodiments of the inventive concept provide a method of driving the test system.

In accordance with an exemplary embodiment of the inventive concept, a test system includes a test device configured to transmit an input signal and a control signal to at least one CMOS image sensor via a probe card, and an interface board configured to map the probe card and the test device. The interface board includes an output receiver configured to receive an image signal from the at least one CMOS image sensor and transform the image signal into image data.

In an exemplary embodiment of the inventive concept, the output receiver may transmit the image data to a computer, and the computer may include a graphics processing unit configured to transform the image data into a two-dimensional (2D) image.

In an exemplary embodiment of the inventive concept, the output receiver may include a high-speed signal receiver configured to receive high-speed serial data from the at least one CMOS image sensor, and an image signal interpreter configured to synchronize the high-speed serial data.

In an exemplary embodiment of the inventive concept, the high-speed signal receiver may measure a channel voltage corresponding to the image signal while receiving the image signal.

In an exemplary embodiment of the inventive concept, the high-speed signal receiver may compare the channel voltage with a reference voltage, and when a result of the comparing indicates that the reference voltage is higher than the channel voltage, the channel voltage is set to the reference voltage.

In an exemplary embodiment of the inventive concept, the image signal may include a start of transmission (SOT) signal, and the image signal interpreter may synchronize the image signal based on the SOT signal.

In an exemplary embodiment of the inventive concept, a plurality of input probes of the probe card may be electrically connected to input pads of the at least one CMOS image sensor, respectively, a plurality of output probes of the probe card may be electrically connected to output pads of the at least one CMOS image sensor, respectively, and the plurality of output probes may be connected to the output receiver.

In an exemplary embodiment of the inventive concept, the computer may determine whether the at least one CMOS image sensor passes or fails according to the 2D image.

In an exemplary embodiment of the inventive concept, the test system may further include a power supply configured to supply power to the at least one CMOS image sensor.

In accordance with an exemplary embodiment of the inventive concept, a method of driving a test system that tests at least one CMOS image sensor includes supplying power to the at least one CMOS image sensor using an expansion board; transmitting an image signal from the at least one CMOS image sensor to the expansion board and measuring a channel voltage of the image signal; transforming the image signal into image data using the expansion board; and transmitting the image data to a graphics processing unit.

In an exemplary embodiment of the inventive concept, the measuring of the channel voltage may include controlling a switch to apply the channel voltage to a comparator; applying a reference voltage to the comparator; and comparing the channel voltage with the reference voltage using the comparator.

In an exemplary embodiment of the inventive concept, the method may further include setting a start voltage of the reference voltage, an end voltage of the reference voltage, and an interval voltage, and setting the reference voltage to the start voltage.

In an exemplary embodiment of the inventive concept, the comparing of the channel voltage with the reference voltage may include setting the channel voltage to the reference voltage when the reference voltage is higher than the channel voltage.

In an exemplary embodiment of the inventive concept, the comparing of the channel voltage with the reference voltage may include increasing the reference voltage by the interval voltage when the reference voltage is lower than the channel voltage, and applying the increased reference voltage to the comparator.

In an exemplary embodiment of the inventive concept, the method may further include transforming the image data into a 2D image using the graphics processing unit.

In accordance with an exemplary embodiment of the inventive concept, a test system includes a probe card including input probes configured to connect to input pads of a device-under-test (DUT) and output probes configured to connected to output pads of the DUT; and an interface board configured to provide test signals from a test device to the DUT via the input probes of the probe card and receive test data from the DUT via the output probes of the probe card.

The DUT includes a CMOS) image sensor.

The interface board includes a power supply configured to supply power to another DUT.

The interface board includes a receiver configured to receive high speed serial data from the DUT and low speed parallel data from the DUT.

The interface board is configured to measure a channel voltage of the test data as it is being received by the interface board.

### BRIEF DESCRIPTION OF THE DRAWINGS

The above and other features of the inventive concept will become more apparent by describing in detail exemplary embodiments thereof with reference to the accompanying drawings, in which:

FIG. 1 is a block diagram of a test system in accordance with an exemplary embodiment of the inventive concept;

FIG. 2 is a diagram illustrating a device under test (DUT) and a probe card illustrated in FIG. 1, according to an exemplary embodiment of the inventive concept;

FIGS. 3A and 3B illustrate a connection between an input and an output of the test system of FIG. 1, according to an exemplary embodiment of the inventive concept;

FIG. 4 is a block diagram of an output receiver of FIG. 1, according to an exemplary embodiment of the inventive concept;

FIG. 5 is a block diagram of a high-speed signal receiver of FIG. 4, according to an exemplary embodiment of the inventive concept;

FIG. 6A is a graph illustrating an operation of a first comparator of FIG. 5, according to an exemplary embodiment of the inventive concept;

FIG. 6B is a graph illustrating an operation of a third comparator of FIG. 5, according to an exemplary embodiment of the inventive concept;

FIG. 7 is a flowchart illustrating operations of the first and third comparators of FIG. 5, according to an exemplary embodiment of the inventive concept;

FIG. 8A illustrates a mobile industry processor interface (MIPI) image signal;

FIG. 8B is a block diagram of an image signal interpreter of FIGS. 4 and 5, according to an exemplary embodiment of the inventive concept;

FIG. 9 is a block diagram of a computer of FIG. 1, according to an exemplary embodiment of the inventive concept;

FIG. 10 illustrates a program executed by a central processing unit (CPU) of FIG. 9, according to an exemplary embodiment of the inventive concept; and

FIG. 11 illustrates a program executed by a graphics processing unit (GPU) of FIG. 9, according to an exemplary embodiment of the inventive concept.

### DETAILED DESCRIPTION OF THE EMBODIMENTS

Exemplary embodiments of the inventive concept will be described more fully hereinafter with reference to the accompanying drawings. However, the inventive concept may be embodied in many different forms and should not be construed as being limited to the embodiments set forth herein.

It will be understood that when an element or layer is referred to as being “on,” “connected to,” or “coupled to” another element or layer, it can be directly on, connected, or coupled to the other element or layer, or intervening elements or layers may be present.

As used herein, the singular forms “a,” “an,” and “the” are intended to include the plural forms as well, unless the context clearly indicates otherwise.

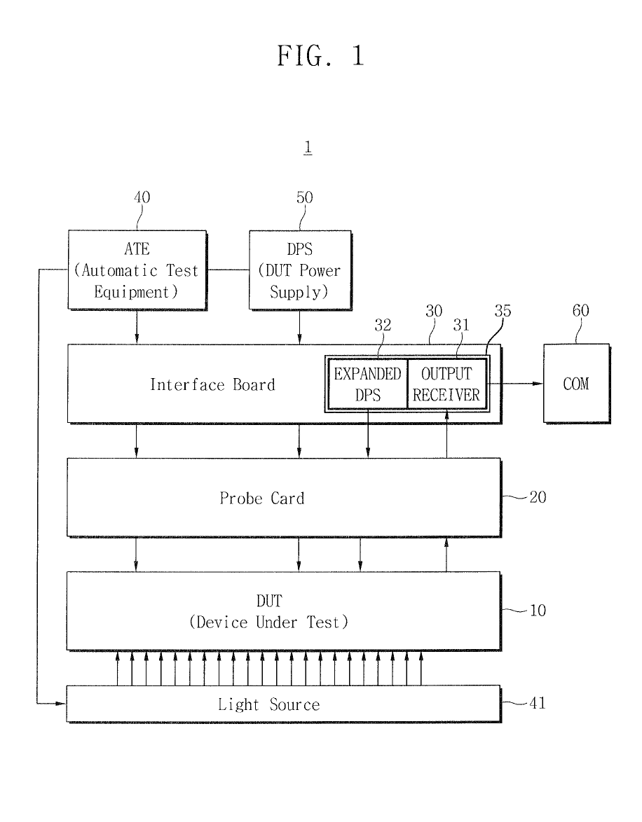

FIG. 1 is a block diagram of a test system 1 in accordance with an exemplary embodiment of the inventive concept.

Referring to FIG. 1, the test system 1 includes a device under test (DUT) 10 which is a test target, a probe card 20 that is directly electrically connected to the DUT 10 using probes thereof, and an interface board 30 that maps the probe card 20 and automatic test equipment (ATE) 40 to each other.

The DUT 10 is a device that is to be verified before it is released to market. The DUT 10 in accordance with an exemplary embodiment of the inventive concept is a complementary metal-oxide semiconductor (CMOS) image sensor; however, the inventive concept is not limited thereto. For example, other image sensors or image forming devices may be the DUT 10. The DUT 10 may be at least one CMOS image sensor formed on a wafer or a CMOS image sensor manufactured in a package form.

In general, the CMOS image sensor is divided into a CMOS image sensor (CIS) unit and an image signal processing (ISP) unit. The CIS unit encodes an amount of input light into a signal. The ISP unit performs image processing to reconstruct the signal received from the CIS unit through interpolation. The CIS unit and the ISP unit may be formed as separate chips or may be formed as a single chip using system on chip (SOC) technology. The CIS unit includes a plurality of pixels arranged in a matrix at intersections of a plurality of rows and a plurality of columns. Each of the plurality of pixels transforms an electric charge induced by input light into a voltage. The voltage generated in analog form from each of the plurality of pixels is transformed into digital data through correlated double sampling (CDS). The digital data is input to the ISP unit and is then reconstructed as an image signal.

A final output signal of the CMOS image sensor is generated by the ISP unit. Thus, an output of the ISP unit can be used to test operating characteristics of the CMOS image sensor. Since hundred of thousands to millions of unit pixels are included in the CMOS image sensor, it takes a lot of time to test all of the pixels.

The probe card 20 includes a number of probes that correspond to a number of input/output pads or pins of the DUT 10 and via through which the DUT 10 is directly electrically connected to the probe card 20. For example, when the number of the input/output pads of the DUT 10 is ten and the number of probes of the probe card 20 is 100, the ATE 40 may test ten DUTs 10 at the same time. However, in general, the number of probes of the probe card 20 is limited by a number of channels that the ATE 40 provides.

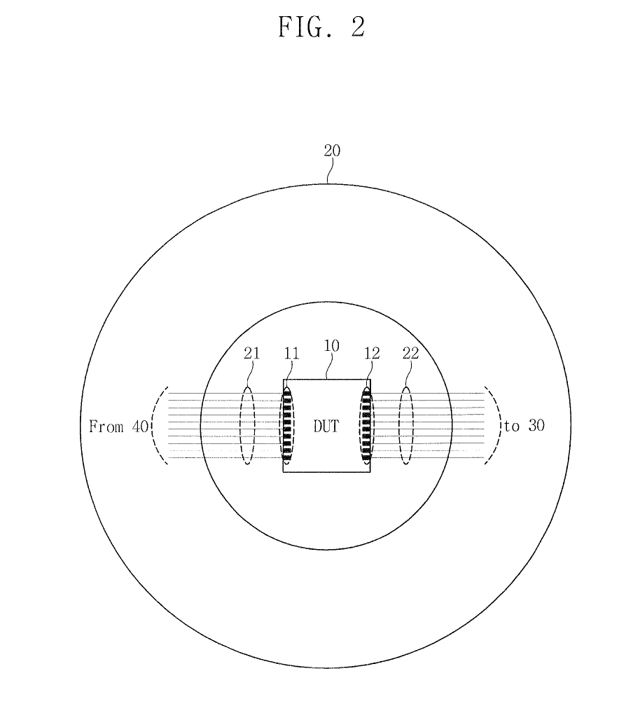

The ATE 40 is connected to the DUT 10 via input probes of the probe card 20, and output probes of the probe card 20 connected to the DUT 10 are connected to the interface board 30. Thus, the probe card 20 in accordance with an exemplary embodiment of the inventive concept may include probes, the number of which is greater than the number of channels that the ATE 40 provides. A structure of the probe card 20 will be described in detail with reference to FIG. 2 below.

The interface board 30 maps the probe card 20 and the ATE 40 to each other. In addition, the interface board 30 includes an expansion board 35 configured to receive an output signal of the DUT 10 and supply power to an additional DUT 10.

The expansion board 35 in accordance with an exemplary embodiment of the inventive concept includes an output receiver 31 configured to receive the output signal of the DUT 10 via the probe card 20, and a expanded DUT power supply (DPS) 32 configured to supply power to the additional DUT 10. The expansion board 35 may be easily attached to and detached from the interface board 30.

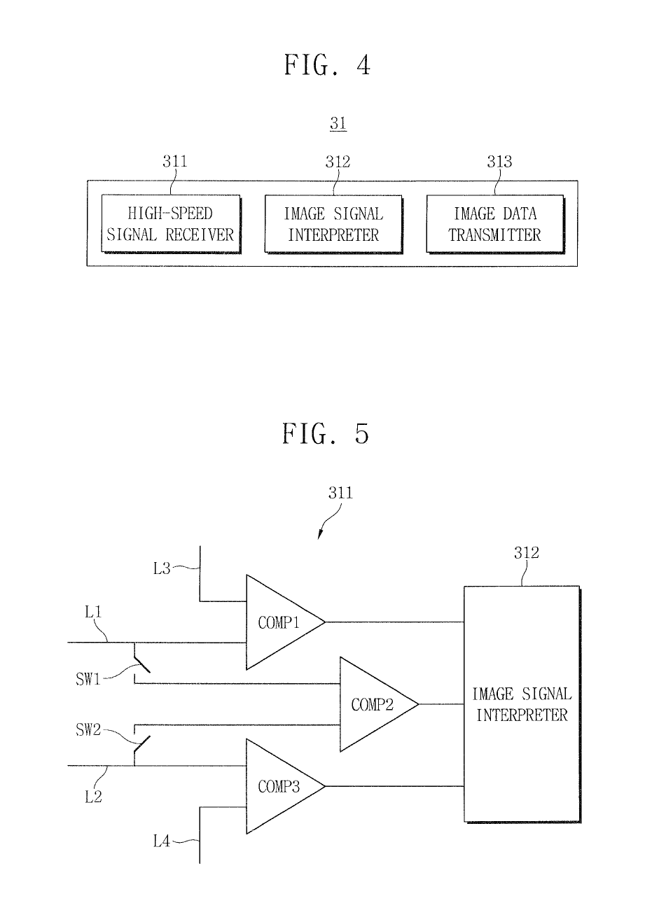

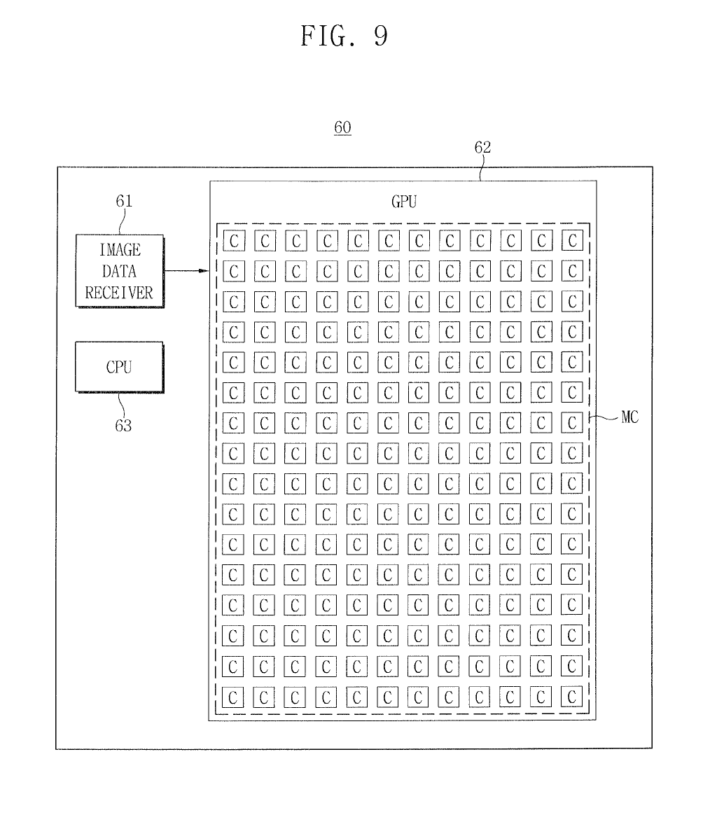

The output receiver 31 receives an image signal of the DUT 10 transmitted from the output probes of the probe card 20. The output receiver 31 transmits the image signal to a computer 60. The computer 60 transforms the image signal into a two-dimensional (2D) image and determines whether the DUT 10 passes or fails. The structure and operations of the output receiver 31 will be described in detail with reference to FIGS. 4 and 5 below. The structure and operations of the computer 60 will be described in detail with reference to FIG. 9 below.

The ATE 40 includes a light source 41 configured to deliver an input (e.g., light) to the DUT 10. The light source 41 may input information regarding various intensities of illumination to the DUT 10. In other words, the ATE 40 may control the light source 41 to output information regarding various brightnesses, e.g., various intensities of illumination, to the DUT 10. The DUT 10 transmits an output signal corresponding to the input intensities of illumination, e.g., an image signal, to the output receiver 31 via the output probes of the probe card 20.

FIG. 2 is a diagram illustrating the DUT 10 and the probe card 20 illustrated in FIG. 1, according to an exemplary embodiment of the inventive concept.

Although FIGS. 1 and 2 illustrate that the probe card 20 is electrically connected to one DUT 10, the probe card 20 in accordance with an exemplary embodiment of the inventive concept may be electrically connected to two or more DUTs 10.

The DUT 10 includes a plurality of input pads 11 and a plurality of output pads 12. Each of the plurality of input pads 11 is electrically connected to one of a plurality of input probes 21. In addition, each of the plurality of output pads 12 is electrically connected to one of a plurality of output probes 22. The plurality of input probes 21 are connected to the ATE 40 via the interface board 30. The plurality of output probes 22 are connected to the interface board 30.

The DUT 10 receives an input and a control signal from the ATE 40 via each of the plurality of input probes 21. In addition, the DUT 10 transmits an image signal to the interface board 30 via each of the plurality of output probes 22. In other words, since the ATE 40 does not receive an output signal of the DUT 10, channels of the ATE 40 that are conventionally used as output channels may be used as input channels for an additional DUT 10. In addition, the interface board 30 includes the expanded DPS 32 to supply power to the additional DUT 10.

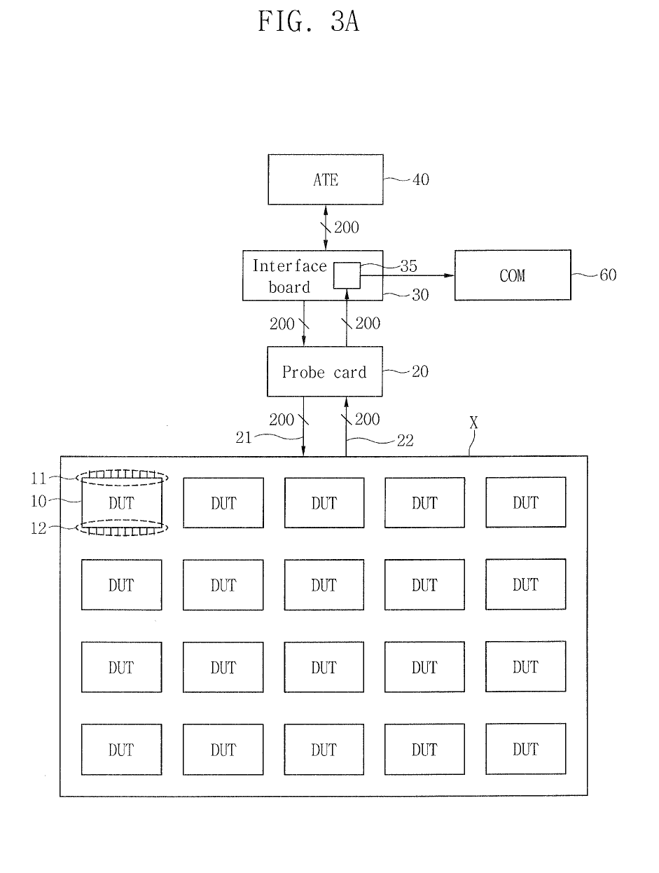

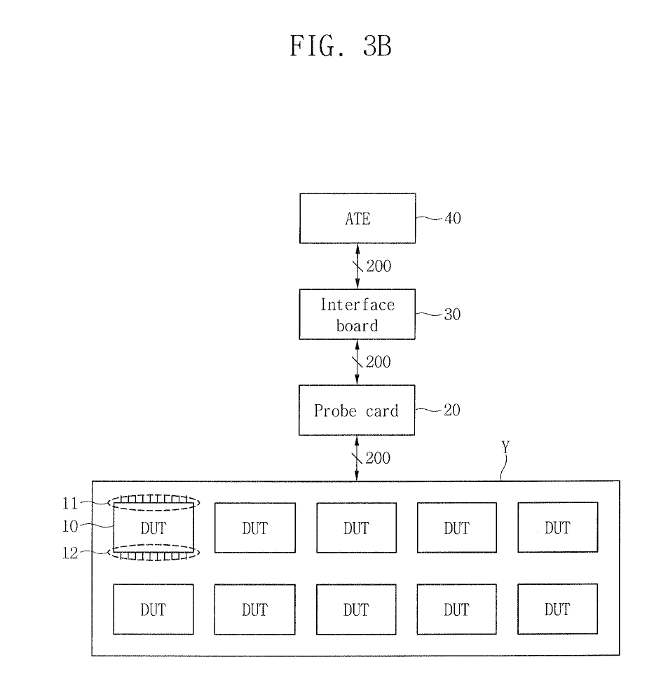

The ATE 40 may test at least two DUTs 10 at the same time. For example, a number of DUTs 10 that the ATE 40 is capable of testing at the same time depends on a number of channels of the ATE 40. A method of calculating a number of added DUTs 10, which is performed by the test system 1, in accordance with an exemplary embodiment of the inventive concept will be described in detail with reference to FIGS. 3A and 313 below.

FIGS. 3A and 3B illustrate a connection between an input and an output of the test system 1 of FIG. 1, according to an exemplary embodiment of the inventive concept.

A total number of DUTs 10 that the ATE 40 in accordance with an exemplary embodiment of the inventive concept is capable of testing at the same time is a quotient X obtained by dividing a number of channels that the ATE 40 has by a number of input channels that the ATE 40 provides to one DUT 10.

Conventionally, a total number of DUTs 10 that the ATE 40 is capable of testing at the same time is a quotient Y obtained by dividing the number of channels that the ATE 40 has by a number of input and output channels that the ATE 40 provides to one DUT 10.

Thus, a number of additional DUTs 10 is equal to the difference between the quotients X and Y. FIG. 3A illustrates a method of calculating the quotient X, and FIG. 3B illustrates a method of calculating the quotient Y.

Referring to FIG. 3A, it is assumed that the number of channels that the ATE 40 has is 200, the number of the input pads 11 of the DUT 10 is 10, and the number of the output pads 12 of the DUT 10 is 10.

The channels of the ATE 40 are connected to only the input pads 11 of the DUT 10 via the input probes 21 of the probe card 20, respectively. The output pads of the DUT 10 are connected to the expansion board 35 via the output probes 22 of the probe card 20, respectively. The expansion board 35 is connected to the computer 60.

Accordingly, a total number of DUTs 10 that may be simultaneously tested by the ATE 40 in accordance with an exemplary embodiment of the inventive concept is 200/10, e.g., 20. In other words, the quotient X is 20.

Referring to FIG. 3B, it is assumed that the number of channels that the ATE 40 provides is 200, the number of the input pads 11 of the DUT 10 is 10, and the number of the output pads 12 of the DUT 10 is 10.

The channels of the ATE 40 are connected to the input pads 11 and the output pads 12 of the DUT 10 via the probe card 20, respectively. In general, a total number of DUTs 10 that may be simultaneously tested by the ATE 40 is 200/20, e.g., 10. In other words, the quotient Y is 10.

In comparison, a number of DUTs 10 that may be additionally simultaneously tested by the ATE 40 in accordance with an exemplary embodiment of the inventive concept is 20-10, e.g., 10. In other words, the quotient X—the quotient Y is 10.

Accordingly, the expansion board 35 in accordance with an exemplary embodiment of the inventive concept includes the expanded DPS 32 to supply power to ten additional DUTs 10.

FIG. 4 is a block diagram of the output receiver 31 of FIG. 1, according to an exemplary embodiment of the inventive concept.

Referring to FIGS. 1 and 4, the output receiver 31 includes a high-speed signal receiver 311, an image signal interpreter 312, and an image data transmitter 313.

The DUT 10 is a CMOS image sensor. CMOS image sensors may employ a mobile industry processor interface (MIPI) which enables serial high-speed data communication with a mobile system.

The MIPI is a serial interface that connects hardware and software between a processor and peripheral devices. Since the MIPI is a high-speed digital serial interface, battery consumption is low and high-speed signal transmission may be performed using a high bandwidth.

An output signal of the DUT 10 is supplied to the high-speed signal receiver 311 using the MIPI, e.g., a high-speed digital serial interface. The high-speed signal receiver 311 transmits the output signal of the DUT 10, e.g., an image signal, to the image signal interpreter 312.

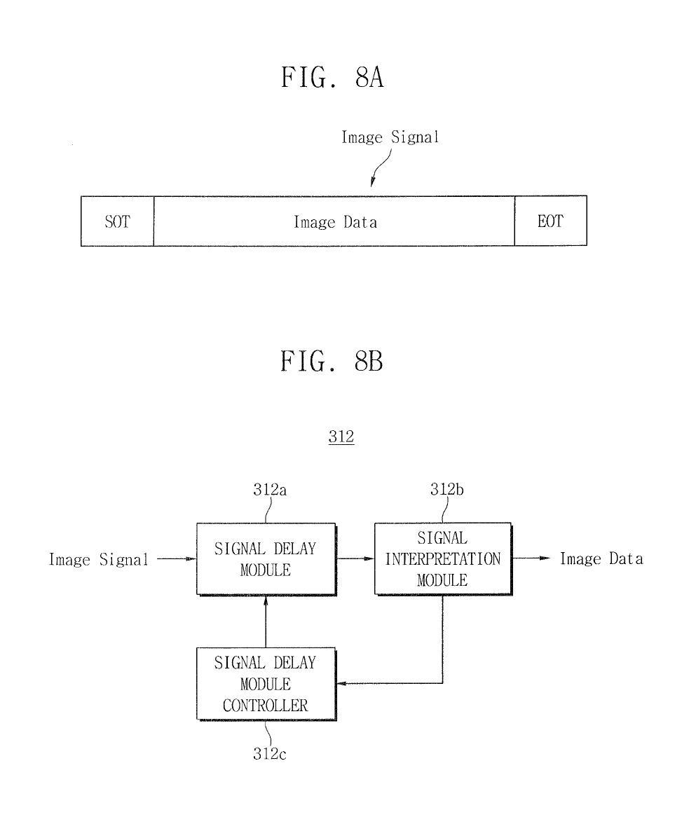

The image signal interpreter 312 interprets the image signal received from the high-speed signal receiver 311. When a high-speed serial signal (e.g., the image signal) is distorted in shape or is delayed in transmission, the image signal interpreter 312 corrects such an error. The image signal interpreter 312 will be described in detail with reference to FIGS. 8A and 8B below.

The image signal interpreter 312 transmits the interpreted image signal (e.g., image data) to the image data transmitter 313. The image data transmitter 313 transmits the image data to the computer 60.

In general, low-specification test apparatuses are capable of testing only devices that transmit data in parallel at low speeds. However, high-resolution CMOS image sensors used in smart phones may employ the MIPI, e.g., a high-speed serial data transmission method. Thus, such low-specification test apparatuses cannot test high-resolution CMOS image sensors employing the MIPI.

However, the test system 1 in accordance with an exemplary embodiment of the inventive concept includes the expansion board 35 capable of receiving high-speed serial data. More specifically, the expansion board 35 in accordance with an exemplary embodiment of the inventive concept includes the output receiver 31 corresponding to a data interface of the DUT 10, e.g., the MIPI.

For example, when the DUT 10 employs a low-speed parallel data transmission method, the expansion board 35 may use the output receiver 31 capable of receiving low-speed parallel data. When the DUT 10 employs a high-speed serial data transmission method such as the MIPI, the expansion board 35 may use the output receiver 31 capable of receiving high-speed serial data. Thus, the test system 1 in accordance with an exemplary embodiment of the inventive concept may also use a low-specification test apparatus.

FIG. 5 is a block diagram of the high-speed signal receiver 311 of FIG. 4, according to an exemplary embodiment of the inventive concept.

Referring to FIGS. 4 and 5, the high-speed signal receiver 311 is configured according to MIPI signal standards. Specifically, the high-speed signal receiver 311 includes first to third comparators COMP1 to COMP3 and first and second switches SW1 and SW2.

The first comparator COMP1 and the third comparator COMP3 operate in a low-power mode, and the second comparator COMP2 operates in a high-speed operating mode. Outputs of the first to third comparators COMP1 to COMP3 are transmitted to the image signal interpreter 312.

The DUT 10 transmits an image signal via first and second lines L1 and L2. The first and second lines L1 and L2 receive the image signal according to high-speed serial differential standards.

The image signal received via the first and second lines L1 and L2 is transmitted to the first and third comparators COMP1 and COMP3 or the second comparator COMP2 according to operations of the first and second switches SW1 and SW2. A reference voltage Vref is applied to third and fourth lines L3 and L4. The reference voltage Vref applied to the third and fourth lines L3 and L4 is applied to the first comparator COMP1 and the third comparator COMP3.

If a current mode is the low-power mode, the first and second switches SW1 and SW2 are opened. The DUT 10 transmits the image signal to the first comparator COMP1 and the third comparator COMP3 via the first and second lines L1 and L2. Each of the first comparator COMP1 and the third comparator COMP3 transmits a comparison signal obtained through a comparison operation to the image signal interpreter 312.

If a current mode is the high-speed operating mode, the first and second switches SW1 and SW2 are closed. The DUT 10 transmits the image signal to the second comparator COMP2 via the first and second lines L1 and L2. The second comparator COMP2 transmits a comparison signal obtained through a comparison operation to the image signal interpreter 312.

In general, the image signal indicating a result of testing the DUT 10 is received via the first and second lines L1 and L2. However, when voltages of the first and second lines L1 and L2 are measured, noise may be generated in the first and second lines L1 and L2. Thus, the voltages of the first and second lines L1 and L2 may be measured separately from the test of the DUT 10.

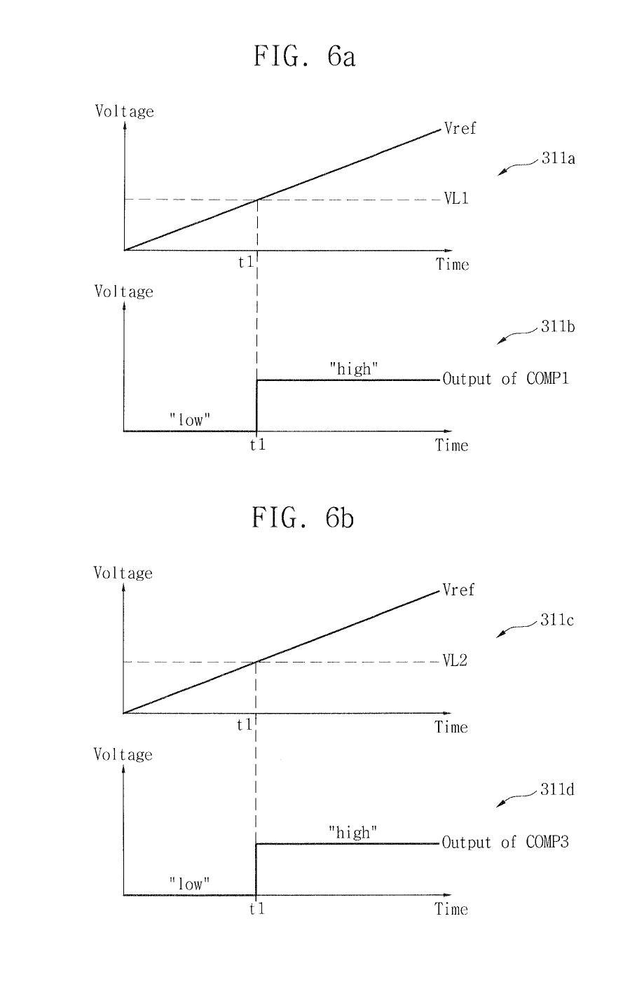

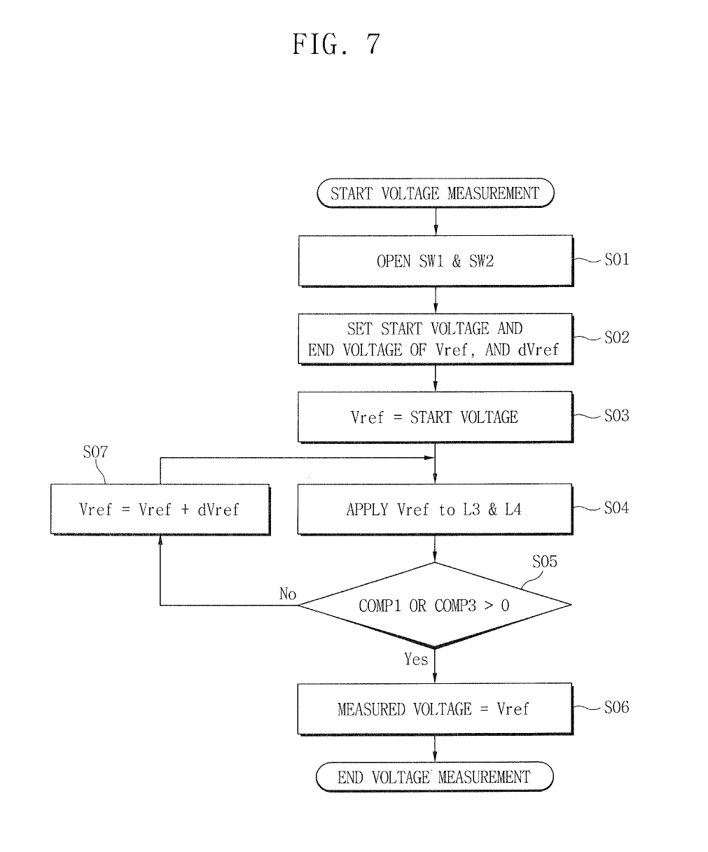

However, the high-speed signal receiver 311 in accordance with an exemplary embodiment of the inventive concept is capable of measuring a channel voltage according to an output of a MIPI signal while testing the DUT 10. This is so, because the first comparator COMP1 and the third comparator COMP3 compare the reference voltage Vref with each of the voltages of the first and second lines L1 and L2 to measure the channel voltage according to the output of the MIPI signal in the low-power mode. A method of measuring the channel voltage according to the output of the MIPI signal, which is performed by the high-speed signal receiver 311, will now be described in detail with reference to FIGS. 6A, 6B, and 7.

FIG. 6A is a graph illustrating an operation of the first comparator COMP1 of FIG. 5, according to an exemplary embodiment of the inventive concept.

Referring to FIGS. 5 and 6A, a first graph 311a shows an input of the first comparator COMP 1 according to time, and a second graph 311b shows an output of the first comparator COMP1 according to time. In the first and second graphs 311a and 311b, the X-axis denotes time, and the Y-axis denotes voltage.

The first comparator COMP1 operates in a low-power mode. Thus, the first switch SW1 is opened.

The reference voltage Vref increases as time elapses. For example, the reference voltage Vref increases starting from 0V. The reference voltage Vref is applied to the third line L3. A direct-current (DC) voltage VL1 of an output channel of the DUT 10 (hereinafter referred to as ‘channel voltage VL1’) is applied to the first line L1.

The first comparator COMP1 compares the reference voltage Vref with the channel voltage VL1 applied to the first line L1. At a point of time t1, the reference voltage Vref and the channel voltage VL1 applied to the first line L1 become the same. After the point of time t1, the reference voltage Vref becomes higher than the channel voltage VL1 applied to the first line L1.

Until the point of time t1, an output of the first comparator COMP1 is maintained in a logic low state. After the point of time t1, the output of the first comparator COMP1 is maintained in a logic high state. Thus, the channel voltage VL1 applied to the first line L1 becomes equal to an electric potential of the reference voltage Vref at the point of time t1.

FIG. 6B is a graph illustrating an operation of the third comparator COMP3 of FIG. 5, according to an exemplary embodiment of the inventive concept.

Referring to FIGS. 5 and 6B, a third graph 311c shows an input of the third comparator COMP3 according to time, and a fourth graph 311d shows an output of the third comparator COMP3 according to time. In the third and fourth graphs 311c and 311d, the X-axis denotes time, and the Y-axis denotes voltage.

The third comparator COMP3 operates in the low-power mode. Thus, the second switch SW2 is opened.

A reference voltage Vref increases as time elapses. For example, the reference voltage Vref increases starting from 0V. The reference voltage Vref is applied to the fourth line L4. A DC voltage VL2 of an output channel of the DUT 10 (hereinafter referred to as ‘channel voltage VL2’) is applied to the second line L2.

The third comparator COMP3 compares the reference voltage Vref with the channel voltage VL2 applied to the second line L2. At a point of time t1, the reference voltage Vref and the channel voltage VL2 applied to the second line L2 become the same. After the point of time t1, the reference voltage Vref becomes higher than the channel voltage VL2 applied to the second line L2.

Until the point of time t1, an output of the third comparator COMP3 is maintained in a logic low state. After the point of time t1, the output of the third comparator COMP3 is maintained in a logic high state. Thus, the channel voltage VL2 applied to the second line L2 is equal to an electric potential of the reference voltage Vref at the point of time t1.

FIG. 7 is a flowchart illustrating operations of the first and third comparators COMP1 and COMP3 of FIG. 5, according to an exemplary embodiment of the inventive concept.

Referring to FIGS. 5 to 7, in operation S01, the first and second switches SW1 and SW2 are opened.

In operation S02, a start voltage and an end voltage of a reference voltage Vref are set. In addition, an interval voltage dVref is set. The interval voltage dVref is a unit voltage used to increase the reference voltage Vref from the start voltage to the end voltage, in stages or gradually. For example, if it is assumed that the start voltage and the end voltage of the reference voltage Vref are 0V and 2V, respectively, the interval voltage dVref may be set to 0.1 V. In other words, the reference voltage Vref may be increased by 0.1 V from 0V to 2V. Thus, the lower the interval voltage dVref, the more precise the high-speed signal receiver 311 in accordance with an exemplary embodiment of the inventive concept can measure a DC voltage of an output channel.

In operation S03, the reference voltage Vref is set to the start voltage. In other words, an electric potential of the reference voltage Vref is set to 0V.

In operation S04, the reference voltage Vref is applied to the third and fourth lines L3 and L4.

In operation S05, it is determined whether an output of the first comparator COMP1 is logic high. Operation S06 is performed when the output of the first comparator COMP1 is logic high (in other words, when the reference voltage Vref is higher than the channel voltage VL1), and operation S07 is performed when the output of the first comparator COMP1 is not logic high (in other words, when the reference voltage Vref is not higher than the channel voltage VL1).

Similarly, in operation S05, it is determined whether an output of the third comparator COMP3 is logic high. Operation S06 is performed when the output of the third comparator COMP3 is logic high (in other words, when the reference voltage Vref is higher than the channel voltage VL2), and operation S07 is performed when the output of the third comparator COMM is not logic high (in other words, when the reference voltage Vref is not higher than the channel voltage VL2).

In operation S06, the channel voltage VL1 or VL2 is set to a current reference voltage Vref.

In operation S07, a new reference voltage Vref is set by adding the interval voltage dVref to the current reference voltage Vref, and operation S04 is performed again.

FIG. 8A illustrates a MIPI image signal.

Referring to FIG. 8A, the image signal includes a start of transmission signal SOT, image data, and an end of transmission signal EOT. The start of transmission signal SOT is a signal indicating the start of the image signal. The end of transmission signal EOT is a signal indicating the end of the image signal.

FIG. 8B is a block diagram of the image signal interpreter 312 of FIGS. 4 and 5, according to an exemplary embodiment of the inventive concept.

Referring to FIGS. 4, 5, 8A, and 8B, the image signal interpreter 312 receives a high-speed serial signal from the high-speed signal receiver 311. During the receiving of this signal, signal distortion or a time delay may occur in the first or second line L1 or L2. The distorted or delayed signal may be a factor that prevents the image signal interpreter 312 from generating normal image data during an image data generation process.

To generate normal image data, the image signal interpreter 312 in accordance with an exemplary embodiment of the inventive concept includes a signal delay module 312a, a signal interpretation module 312b, and a signal delay module controller 312c.

The signal delay module 312a receives the image signal from the high-speed signal receiver 311. The signal interpretation module 312b transforms the image signal into image data and transmits the image data to the image data transmitter 313. The signal interpretation module 312b extracts the image data in synchronization with the start of transmission signal SOT. In other words, the signal interpretation module 312b sets the start of transmission signal SOT as a reference signal during the transformation of the image signal into the image data.

The signal delay module controller 312c determines whether the start of transmission signal SOT of the image signal falls within a normal range. In other words, the signal delay module controller 312c controls the signal delay module 312a to determine whether the start of transmission signal SOT of the image signal falls within the normal range. For example, the signal delay module controller 312c increases or decreases a delay control value of a delay device (not shown) included in the signal delay module 312a so that transmission of the image signal can be delayed.

In addition, the signal delay module controller 312c recognizes a range of the delay control value, e.g., a range from a section in which a determination as to whether the start of transmission signal SOT falls within the normal range starts to a section in which the determination is maintained, as an effective data section.

FIG. 9 is a block diagram of the computer 60 of FIG. 1, according to an exemplary embodiment of the inventive concept.

Referring to FIGS. 1 and 9, the computer 60 in accordance with an exemplary embodiment of the inventive concept may be a personal computer. Otherwise, the computer 60 in accordance with an exemplary embodiment of the inventive concept may be a workstation, a server, a mainframe computer, a super computer, or the like.

The computer 60 in accordance with an exemplary embodiment of the inventive concept includes an image data receiver 61 configured to receive image data, a graphics processing unit (GPU) 62 configured to transform the received image data into a 2D image, and a central processing unit (CPU) 63 configured to control the image data receiver 61 and the GPU 62. The GPU 62 includes multi-cores MC to perform graphic operations in parallel.

In general, a unit core C that is included in the GPU 62 and that performs graphic operations in parallel is a CUDA processor (which is commercially available from Nvidia™) and a stream processor (which is commercially available from AMD™).

In accordance with an exemplary embodiment of the inventive concept, the GPU 62 may be a part of the CPU 63 or a chip disposed separately from the CPU 63.

Although an operation of transforming the image data into a 2D image is not complicated, the number of calculations is high. Thus, when the CPU 63 performs such conversions, the number of calculations is high and thus takes a lot of time. In other words, although the performance of the CPU 63 is much higher than that of a unit core C, the function of transforming a large amount of image data into a 2D image may be done more rapidly by the multi-cores MC rather than by one CPU 63.

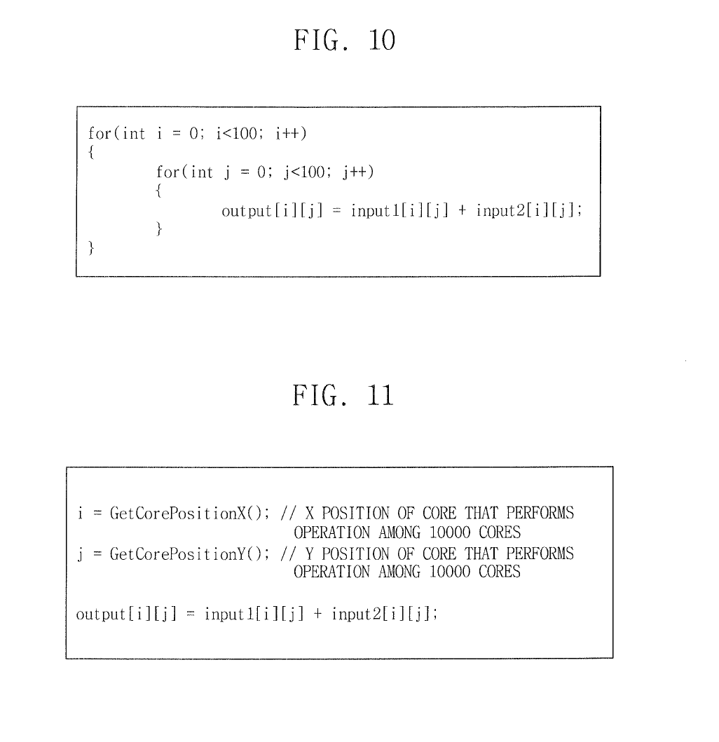

FIG. 10 illustrates a program executed by the CPU 63 of FIG. 9, according to an exemplary embodiment of the inventive concept.

Referring to FIGS. 9 and 10, the CPU 63 inputs variables i, e.g., ‘0’ to ‘100’, and variables j, e.g., ‘0’ to ‘100’, with respect to the variables i, and calculates an output that is the sum of a first input input1 and a second input input2. Thus, the CPU 63 may produce a 2D image which is an output displayed in 100×100 matrices by performing a loop a total of 10,000 times.

FIG. 11 illustrates a program executed by the GPU 62 of FIG. 9, according to an exemplary embodiment of the inventive concept.

Referring to FIGS. 9 and 11, the GPU 62 includes the multi-core MC. For example, it is assumed that the multi-core MC includes 10,000 unit cores C.

The multi-core MC executes a program GetCorePositionX, GetCorePositionY of producing an output[i][j] by adding a first input[i][j] and a second input[i][j] together. Here, the calculation is ended when each of the cores C included in the multi-core MC performs an operation once.

As can be seen, the more data in a 2D image, the more loops the CPU 63 performs. However, the GPU 62 may perform operations in parallel using the multi-cores MC to process the 2D image more quickly.

A test system in accordance with an exemplary embodiment of the inventive concept may use output channels of a CMOS image sensor as input channels, and thus is capable of testing more CMOS image sensors for a given time. Accordingly, the test system may reduce time for testing a CMOS image sensor.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A test system, comprising:
a test device configured to transmit an input signal and a control signal to at least one complementary metal-oxide semiconductor (CMOS) image sensor via a probe card; and
an interface board configured to map the probe card and the test device,
wherein the interface board comprises an output receiver configured to receive an image signal from the at least one CMOS image sensor and transform the image signal into image data.

2. The test system of claim 1, wherein the output receiver transmits the image data to a computer, and
the computer comprises a graphics processing unit configured to transform the image data into a two-dimensional (2D) image.

3. The test system of claim 2, wherein the computer determines whether the at least one CMOS image sensor passes or fails according to the 2D image.

4. The test system of claim 1, wherein the output receiver comprises:
a high-speed signal receiver configured to receive high-speed serial data from the at least one CMOS image sensor; and
an image signal interpreter configured to synchronize the high-speed serial data.

5. The test system of claim 4, wherein the high-speed signal receiver measures a channel voltage corresponding to the image signal while receiving the image signal.

6. The test system of claim 5, wherein the high-speed signal receiver compares the channel voltage with a reference voltage, and
when a result of the comparing indicates that the reference voltage is higher than the channel voltage, the channel voltage is set to the reference voltage.

7. The test system of claim 4, wherein the image signal comprises a start of transmission (SOT) signal, and
the image signal interpreter synchronizes the image signal based on the SOT signal.

8. The test system of claim 1, wherein a plurality of input probes of the probe card are electrically connected to input pads of the at least one CMOS image sensor, respectively,
a plurality of output probes of the probe card are electrically connected to output pads of the at least one CMOS image sensor, respectively, and
the plurality of output probes are connected to the output receiver.

9. The test system of claim 1, further comprising a power supply configured to supply power to the at least one CMOS image sensor.

10. A method of driving a test system that tests at least one complementary metal-oxide semiconductor (CMOS) image sensor, comprising:
supplying power to the at least one CMOS image sensor using an expansion board;
transmitting an image signal from the at least one CMOS image sensor to the expansion board and measuring a channel voltage of the image signal;
transforming the image signal into image data using the expansion board; and
transmitting the image data to a graphics processing unit.

11. The method of claim 10, wherein the measuring of the channel voltage comprises:
controlling a switch to apply the channel voltage to a comparator;
applying a reference voltage to the comparator; and
comparing the channel voltage with the reference voltage using the comparator.

12. The method of claim 11, further comprising:
setting a start voltage of the reference voltage, an end voltage of the reference voltage, and an interval voltage; and
setting the reference voltage to the start voltage.

13. The method of claim 12, wherein the comparing of the channel voltage with the reference voltage comprises setting the channel voltage to the reference voltage when the reference voltage is higher than the channel voltage.

14. The method of claim 12, wherein the comparing of the channel voltage with the reference voltage comprises:
increasing the reference voltage by the interval voltage when the reference voltage is lower than the channel voltage; and
applying the increased reference voltage to the comparator.

15. The method of claim 10, further comprising transforming the image data into a two-dimensional (2D) image using the graphics processing unit.

16. A test system, comprising:
a probe card including input probes configured to connect to input pads of a device-under-test (DUT) and output probes configured to connected to output pads of the DUT; and
an interface board configured to provide test signals from a test device to the DUT via the input probes of the probe card and receive test data from the DUT via the output probes of the probe card.

17. The test system of claim 16, wherein the DUT includes a complementary metal-oxide semiconductor (CMOS) image sensor.

18. The test system of claim 16, wherein the interface board includes a power supply configured to supply power to another DUT.

19. The test system of claim 16, wherein the interface board includes a receiver configured to receive high speed serial data from the DUT and low speed parallel data from the DUT.

20. The test system of claim 16, wherein the interface board is configured to measure a channel voltage of the test data as it is being received by the interface board.
